(19) United States
(12) Patent Application Publication
(10) Pub. No.: US 2022/0224313 A1
(43) Pub. Date: Jul. 14, 2022

(54) SYSTEM AND METHOD FOR OPTIMIZING SIGNAL PROCESSING AND STORAGE USING FREQUENCY-TIME DOMAIN CONVERSION

(71) Applicant: Neapco Intellectual Property Holdings, LLC, Farmington Hills, MI (US)

(72) Inventors: Mohan Kumaraswamy, Bengaluru (IN); Alia Comai, Northville, MI (US); Phil Kennedy, Farmington Hills, MI (US); Kiran Soni, Rochester Hills, MI (US); John Ogger, Farmington Hills, MI (US)

(21) Appl. No.: 17/571,722

(22) Filed: Jan. 10, 2022

Related U.S. Application Data
(60) Provisional application No. 63/135,862, filed on Jan. 11, 2021.

(51) Int. Cl. H03H 17/04; H03H 17/02

(52) U.S. Cl. CPC H03H 17/045; H03H 17/0213

(57) ABSTRACT

An audio processing system and method of operating the system are provided. The system includes a memory storing a plurality of frequency domain sound recording samples represented and stored in a frequency domain and being previously converted from a plurality of sound recording samples represented in a time domain. The system also includes at least one processing unit coupled to the memory and is configured to read the plurality of frequency domain sound recording samples from the memory. The at least one processing unit is also configured to process the plurality of frequency domain sound recording samples.

### CROSS REFERENCE TO RELATED APPLICATIONS

This utility application claims the benefit of U.S. Provisional Application No. 63/135,862 filed Jan. 11, 2021. The entire disclosure of the above application is incorporated herein by reference.

### FIELD

The present disclosure relates generally to audio processing systems. More particularly, the present disclosure is directed to an audio processing system and method for optimizing signal processing and storage using frequency-time domain conversion.

### BACKGROUND

This section provides background information related to the present disclosure which is not necessarily prior art.

Electric vehicles are typically quieter in operation than their internal combustion counterparts. While such quiet operation may be advantageous in some situations, it can be undesirable in other situations. For example, when being around vehicles or roadways, pedestrians are accustomed to hearing cars, trucks, and motorcycles. Consequently, the pedestrians may employ such sounds in knowing when to cross or how close they can safely walk adjacent the roadway. In addition, the quieter operation of electric vehicles may be somewhat disorienting for operators of the vehicle who are more familiar with noise generated by drivelines of internal combustion engines as they operate the vehicle (e.g., hearing an increasing exhaust sound and/or changes in the exhaust note due to gear changes in the transmission). Thus, simulated vehicle noises may be generated and output by the electric vehicle.

An audio processing system 20 that can, for example, be used in the generation of simulated vehicle noises is shown in FIG. 1 and includes a memory 22 storing a plurality of sound recording samples 24 and a plurality of oscillator signals 26. The audio processing system 20 also includes at least one processing unit 28, 30 coupled to the memory 22. The at least one processing unit 28, 30 is configured to read the plurality of sound recording samples 24 and the plurality of oscillator signals 26 from the memory 22. The memory 22 also includes a plurality of filter coefficients 32. The at least one processing unit 28, 30 can include a digital signal processor 28 and a tuning tool 30 configured to be selectively coupled to the digital signal processor 28. The tuning tool 30 can, for example, provide the plurality of filter coefficients 32.

The at least one processing unit 28, 30 includes a plurality of sample playback modules 34 receiving and processing the plurality of sound recording samples 24 as an input and outputting a sample playback output 36. The plurality of sample playback modules 34 are connected together and include a first playback windowing module 38 and a playback fast Fourier transform (FFT) module 40. The first playback windowing module 38 can, for example, isolate and taper a segment of the plurality of sound recording samples 24. After the isolation and tapering of the plurality of sound recording samples 24, the output of the first playback windowing module 38 is converted from a time domain signal to a frequency domain signal by the playback fast Fourier transform (FFT) module 40. The plurality of sample playback modules 34 also includes a playback pitch shift module 42, a playback inverse fast Fourier transform (iFFT) module 44, a second playback windowing module 46, a playback gain control module 48, and a playback filter module 50.

The at least one processing unit 28, 30 also includes a plurality of oscillator modules 52 receiving and processing the plurality of oscillator signals 26 as an input and outputting an oscillator output 54. Similar to the plurality of sample playback modules, the plurality of oscillator modules 52 are connected together and include a first oscillator windowing module 56 and an oscillator fast Fourier transform (FFT) module 58. The first oscillator windowing module 56 can isolate and taper a segment of the plurality of oscillator signals 26. After the isolation and tapering of the plurality of the oscillator signals, the output of the first oscillator windowing module 56 is converted from a time domain signal to a frequency domain signal by the oscillator fast Fourier transform (FFT) module 58. The plurality of oscillator modules 52 also includes an oscillator pitch shift module 60, an oscillator inverse fast Fourier transform (iFFT) module 62, a second oscillator windowing module 64, an oscillator gain control module 66, and an oscillator filter module 68. In addition, the at least one processing unit 28, 30 includes a plurality of noise modules 70 connected together. The plurality of noise modules 70 includes a noise generator module 72, a noise gain control unit 74, and a noise filter module 76. The plurality of noise modules 70 outputs a noise output 78.

The sample playback output 36, the oscillator output 54, and the noise output 78 are all mixed by a mix module 80 of the at least one processing unit 28, 30. The mix module 80 outputs a mix output 82 to an output filter module 84 of the at least one processing unit 28, 30 that is also connected to the memory 22 to receive the plurality of filter coefficients 32. A first filtered mixer output 86 is output from the first FIR filter module 84 to speakers after processing in a first gain and equalization module 88 (e.g., delay, reverb) of the at least one processing unit 28, 30.

Nevertheless, such signal processing and storage in the audio processing system 20 is carried out with time domain signals. Signal processing and storage of such time domain signals requires substantial resources involving a central processing unit (CPU) and memory used for the signal processing and storage. Consequently, processing and storage of signals in the time domain are not necessarily preferable in many instances. Accordingly, there remains a continuing need for an audio processing system capable of more efficiently storing and processing signals.

### SUMMARY

This section provides a general summary of the present disclosure and is not a comprehensive disclosure of its full scope or all of its features, aspects and objectives.

It is an aspect of the present disclosure to provide an audio processing system. The system includes a memory storing a plurality of frequency domain sound recording samples represented and stored in a frequency domain and being previously converted from a plurality of sound recording samples represented in a time domain. The system also includes at least one processing unit coupled to the memory and is configured to read the plurality of frequency domain sound recording samples from the memory. The at least one processing unit is also configured to process the plurality of frequency domain sound recording samples.

In accordance with another aspect, there is provided a method of operating an audio processing system including at least one processing unit coupled to a memory. The method includes the step of converting a plurality of sound recording samples represented in a time domain to a plurality of frequency domain sound recording samples represented in a frequency domain using a processor besides the at least one processing unit. The next step of the method is storing the plurality of frequency domain sound recording samples in the memory. The method proceeds with the step of reading the plurality of frequency domain sound recording samples from the memory. The next step of the method is processing the plurality of frequency domain sound recording samples.

In accordance with an additional aspect, another audio processing system is provided. The audio processing system includes a memory storing a plurality of oscillator frequency and magnitude signals and a single unity sine wave reference table. The system also includes at least one processing unit coupled to the memory and including a plurality of oscillator modules. The at least one processing unit is configured to read the plurality of oscillator frequency and magnitude signals and the single unity sine wave reference table from the memory. The at least one processing unit is also configured to generate and output an oscillator output using the plurality of oscillator modules based on the plurality of oscillator frequency and magnitude signals and the single unity sine wave reference table.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 shows a block diagram of a known audio processing system;

FIG. 2 shows a block diagram of an audio processing system according to aspects of the disclosure;

FIG. 3 shows details of processing carried out by the audio processing system to reduce an amount of processing and storage needed according to aspects of the disclosure;

FIG. 4A shows a sample signal or waveform with a single frequency and amplitude according to aspects of the disclosure;

FIG. 4B shows a single frequency generated 12 kHz sample signal of a waveform having only a single frequency and amplitude, a single frequency generated 24 kHz sample signal, and a single frequency interpolated 24 kHz sample signal according to aspects of the disclosure;

FIGS. 5A and 5B show a comparison of the frequency spectrum of the single frequency generated 24 kHz sample signal to the single frequency interpolated 24 kHz sample signal according to aspects of the disclosure;

FIG. 6 shows a multi-frequency generated 12 kHz sample signal of a waveform having multiple frequencies and varying amplitudes and a multi-frequency interpolated 24 kHz sample signal according to aspects of the disclosure;

FIGS. 7A and 7B show a comparison of the frequency spectrum of the multi-frequency generated 12 kHz sample signal to the multi-frequency interpolated 24 kHz sample signal according to aspects of the disclosure;

FIG. 7C shows the frequencies and amplitudes of the multi-frequency generated 12 kHz sample signal of FIG. 7A according to aspects of the disclosure;

FIG. 8 shows the block diagram of the first audio processing system of FIG. 1 with particular modules or blocks highlighted according to aspects of the disclosure; and

FIGS. 9 and 10A-10B illustrate steps of a method of operating an audio processing system according to aspects of the disclosure.

### DETAILED DESCRIPTION

In the following description, details are set forth to provide an understanding of the present disclosure. In some instances, certain circuits, structures and techniques have not been described or shown in detail in order not to obscure the disclosure.

In general, example embodiments of an audio processing system constructed in accordance with the teachings of the present disclosure will now be disclosed. The example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are described in detail.

To alert pedestrians and/or assist operators of an electric vehicle, simulated vehicle noises may be generated and output by the electric vehicle. The generation of such simulated vehicle noises may require signal processing requiring substantial processing and storage resources, especially when carried out using time domain signals. An application of the audio processing systems disclosed herein is in an electronic unit for generating such simulated vehicle noises for electric vehicles. However, it should be understood that the audio processing system described may be used for myriad other applications.

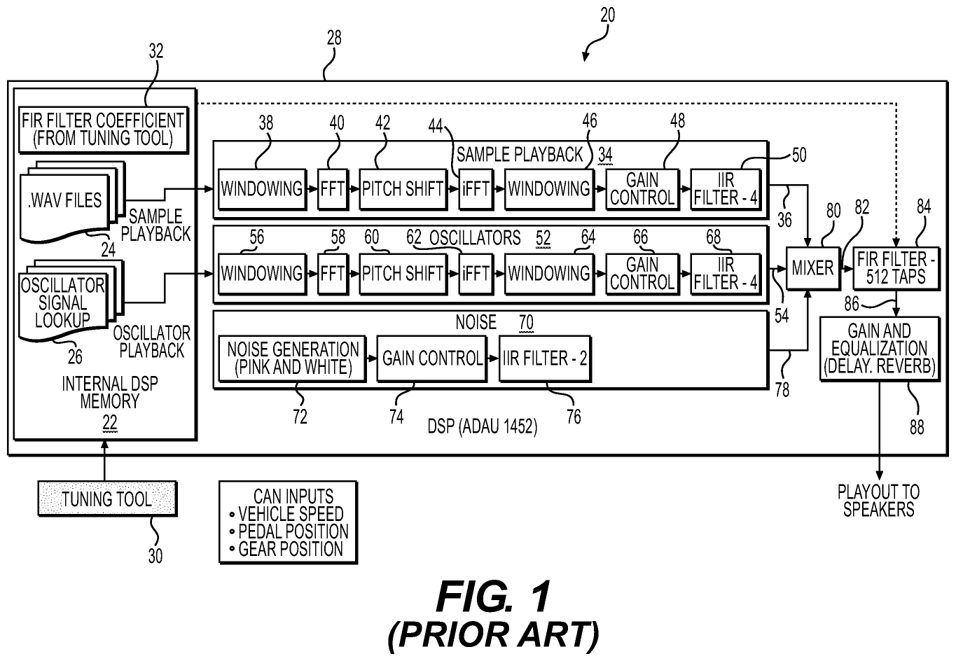

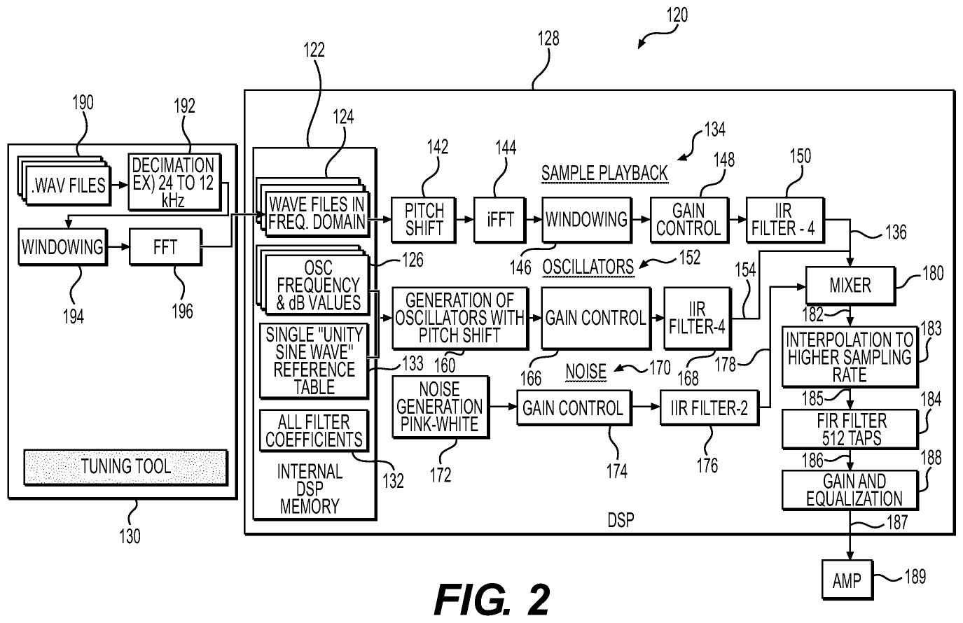

Referring initially to FIG. 2, an audio processing system 120 constructed in accordance with the disclosure is shown. The audio processing system 120 includes a memory 122 storing a plurality of frequency domain sound recording samples 124 represented and stored in a frequency domain that are previously converted from a plurality of sound recording samples represented in a time domain (e.g., plurality of sound recording samples 24 of FIG. 1). The system 120 also includes at least one processing unit 128 coupled to the memory 122 (or the memory 122 can be part of the at least one processing unit 128 as shown). The at least one processing unit 128 is configured to read the plurality of frequency domain sound recording samples 124 from the memory 122. The at least one processing unit 128 is also configured to process the plurality of frequency domain sound recording samples 124.

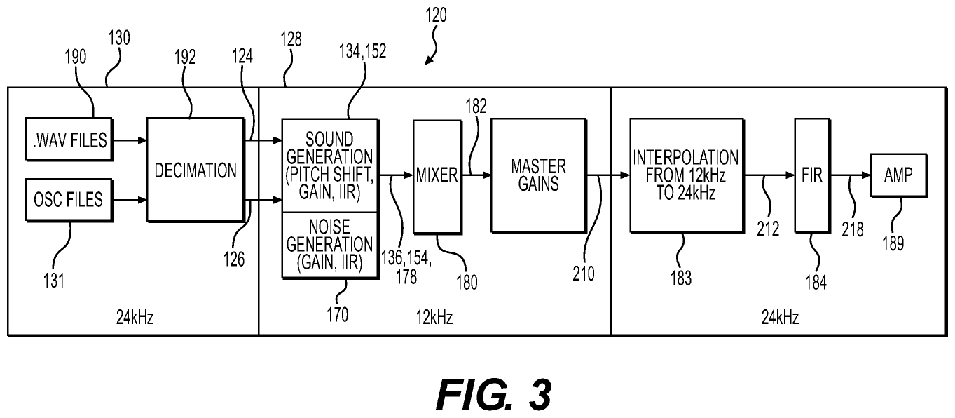

In more detail, the at least one processing unit 128 includes a digital signal processor 128 and the system 120 further includes a tuning tool 130 configured to be selectively coupled to the digital signal processor 128. According to an aspect, the tuning tool 130 is configured to generate, store, and/or modify the plurality of sound recording samples (e.g., .wav files or plurality of sound recording samples) being sampled at a first frequency (e.g., 24 kHz)(block 190). The tuning tool 130 is also configured to decimate the plurality of sound recording samples being sampled at the first frequency (e.g., 24 kHz) to a plurality of decimated sound recording samples being sampled at a second frequency (e.g., 12 kHz) less than the first frequency (block 192). The tuning tool 130 additionally windows the plurality of decimated sound recording samples to output a plurality of windowed decimated sound recording samples (block 194). In addition, the tuning tool 130 is configured to convert the plurality of windowed decimated sound recording samples to the plurality of frequency domain sound recording samples 124 via a fast Fourier transform (FFT) (block 196). As shown, the tuning tool 130 outputs the plurality of frequency domain sound recording samples 124 to the digital signal processor 128 (e.g., to memory 122) thereby reducing an amount of processing required by the digital signal processor 128. While not shown in FIG. 2, the tuning tool 130 is also configured to decimate and convert a plurality of oscillator signals 131 (FIG. 3) sampled at the first frequency (e.g., 24 kilohertz (kHz)) to a plurality of oscillator frequency and magnitude signals 126 represented in the frequency domain.

The memory 122 also includes a plurality of frequency domain filter coefficients 132, the plurality of oscillator frequency and magnitude signals 126, and a single unity sine wave reference table 133. The at least one processing unit 128 is configured to read the plurality of frequency domain sound recording samples 124, the plurality of oscillator frequency and magnitude signals 126, and the plurality of frequency domain filter coefficients 132 from the memory 122. In addition, the at least one processing unit 128 includes a plurality of frequency domain sample playback modules 134 configured to receive and process the plurality of frequency domain sound recording samples 124 as an input and output a sample playback output 136. The plurality of frequency domain sample playback modules 134 are connected together and include a frequency domain playback pitch shift module 142, a frequency domain playback inverse fast Fourier transform (iFFT) module 144, a playback windowing module 146, a playback gain control module 148, and a playback filter module 150 (e.g., infinite impulse response (IIR))(filtering based on the plurality of frequency domain filter coefficients 132). Specifically, the frequency domain playback pitch shift module 142, the frequency domain playback inverse fast Fourier transform (iFFT) module 144, the playback windowing module 146, the playback gain control module 148, and the playback filter module 150 are successively connected to one another serially (i.e., with an output of one serving as an input to a successive one). So, at least some of the processing of the frequency domain sound recording samples 124 is carried out in the frequency domain.

The at least one processing unit 128 also includes a plurality of oscillator modules 152 configured to receive and process the plurality of oscillator frequency and magnitude signals 126 as an input and outputting an oscillator output 154. The plurality of oscillator modules 152 are connected together and include an oscillator generation and pitch shift module 160, an oscillator gain control module 166, and an oscillator filter module 168 (e.g., infinite impulse response (IIR))(filtering based on the plurality of frequency domain filter coefficients 132). More specifically, the oscillator generation and pitch shift module 160, the oscillator gain control module 166, and the oscillator filter module 168 are successively connected to one another serially (i.e., with an output of one serving as an input to a successive one). So, in conjunction with the memory 122 storing the plurality of oscillator frequency and magnitude signals 126 and the single unity sine wave reference table 133, the at least one processing unit 128 is configured to read the plurality of oscillator frequency and magnitude signals 126 and the single unity sine wave reference table 133 from the memory 122. The at least one processing unit 128 generates and outputs the oscillator output 154 using the plurality of oscillator modules 152 based on the plurality of oscillator frequency and magnitude signals 126 and the single unity sine wave reference table 133.

According to another aspect, a pitch shift multiplication factor (based on vehicle speed) can be used for the oscillators (i.e., plurality of oscillator modules 152). Specifically, the pitch shift multiplication factor can be used on a stored base frequency and used to compute a change in frequency Δf in order to generate Θ+ΔΘ of the oscillator. This eliminates pitch shifting and iFFT completely. The instantaneous sample is generated in the time domain. The necessary operations include multiplication/addition with the sine lookup table reference 133.

In addition, the at least one processing unit 128 includes a plurality of noise modules 170 configured to output a noise output 178. The plurality of noise modules 170 are connected together and include a noise generator module 172 (e.g., pink and white noise), a noise gain control unit 174, and a noise filter module 176 (e.g., infinite impulse response (IIR))(filtering based on the plurality of frequency domain filter coefficients 132). In more detail, the noise generator module 172, the noise gain control unit 174, and the noise filter module 176 are successively connected to one another serially (i.e., with an output of one serving as an input to a successive one).

The at least one processing unit 128 additionally includes a mix module 180 configured to receive and mix the sample playback output 136, the oscillator output 154, and the noise output 178 to output a mix output 182. Also included in the at least one processing unit 128 is an interpolation module 183 configured to interpolate the mix output 182 to an interpolated mix output 185 that is sampled at the first frequency. The at least one processing unit 128 includes an output filter module 184 (e.g., finite impulse response (FIR)) configured to receive and filter the interpolated mix output 185 (based on the plurality of frequency domain filter coefficients 132) and output a filtered mixer output 186. Finally, the at least one processing unit 128 includes an output gain and equalization module 188 (e.g., delay, reverb) configured to receive the filtered mixer output 186 and output an equalized filtered mixer output 187 to an amplifier 189.

FIG. 3 shows details of the processing carried out by the audio processing system 120 to reduce an amount of processing and storage needed. So, for example, the plurality of sound recording samples 190 and the plurality of oscillator signals 131 are sampled at a first frequency (e.g., 24 kilohertz (kHz)). The plurality of sound recording samples 190 and the plurality of oscillator signals 131 are decimated and converted to the plurality of frequency domain sound recording samples 124 and the plurality of oscillator frequency and magnitude signals 126 off device (e.g., using the tuning tool 130) via a fast Fourier transform (FFT) and outputted as plurality of frequency domain sound recording samples 124 and the plurality of oscillator frequency and magnitude signals 126 to the digital signal processor 128 (e.g., to memory 122).

The at least one processing unit 128 is configured to read the plurality of frequency domain sound recording samples 124 and the plurality of oscillator frequency and magnitude signals 126 from the memory 122. Again, the plurality of frequency domain sound recording samples 124 and the plurality of oscillator frequency and magnitude signals 126 are sampled at the second frequency (e.g., 12 kHz) that is less than the first frequency (e.g., 24 kHz). The at least one processing unit 128 processes the plurality of frequency domain sound recording samples 124 and the plurality of oscillator frequency and magnitude signals 126 at the second frequency (e.g., 12 kHz). In other words, the audio is processed at the second, lower frequency.

During the processing of the plurality of frequency domain sound recording samples 124 and the plurality of oscillator frequency and magnitude signals 126 at the second frequency, the at least one processing unit 128 is further configured to produce the sample playback output 136 using the plurality of frequency domain sample playback modules 134 and the oscillator output 154 using the plurality of oscillator modules 152 based on the plurality of frequency domain sound recording samples 124 and plurality of oscillator frequency and magnitude signals 126. In addition, the at least one processing unit 128 is configured to produce the noise output 178 using the plurality of noise modules 170. The at least one processing unit 128 is additionally configured to mix the generated sound 136, 154 and generated noise 178 using the mix module 180 and output the mix output 182 at the second frequency. In addition, the at least one processing unit 128 is configured to apply a plurality of master gains to the mix output 182 using master gains 48, 66, 74 and output a mix output with gain signal 210 at the second frequency.

The at least one processing unit 128 is further configured to interpolate the mix output with gain signal 210 at the second frequency to an interpolated mixed mix output 212 using the interpolation module 183. The interpolated mix output 212 is sampled at the first frequency. The decimation by the tuning tool 130, processing at the second frequency (e.g., 12 kHz), and interpolation back to the first frequency (e.g., 24 kHz) helps provide a reduction in the amount of processing (i.e., reduced MIPS) and storage needed.

The at least one processing unit 128 is also configured to filter the interpolated mix output 212 using the output filter module 184 and output a filtered interpolated mix output 218 (based on the plurality of frequency domain filter coefficients 132). The filtered interpolated mix output 218 is then amplified using the amplifier 189 and output as an amplified sound and noise signal to be played using at least one speaker (not shown) coupled to the at least one processing unit 128.

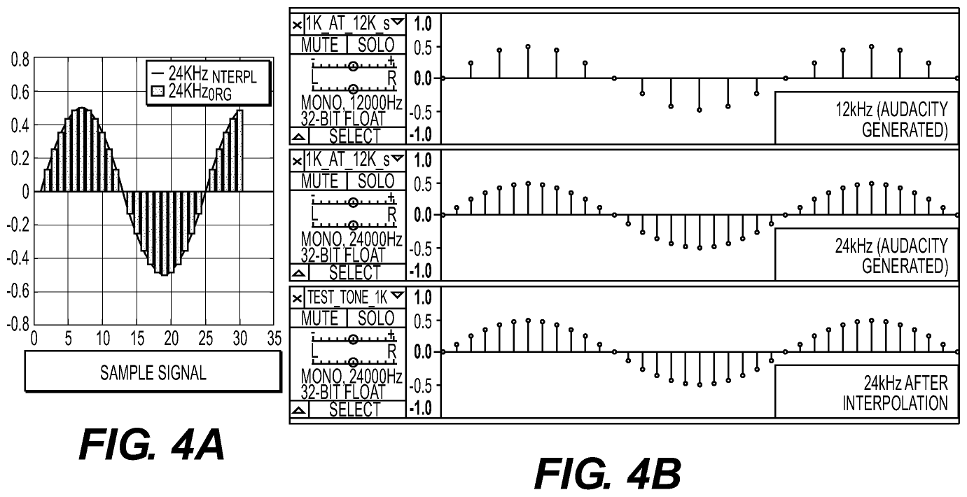

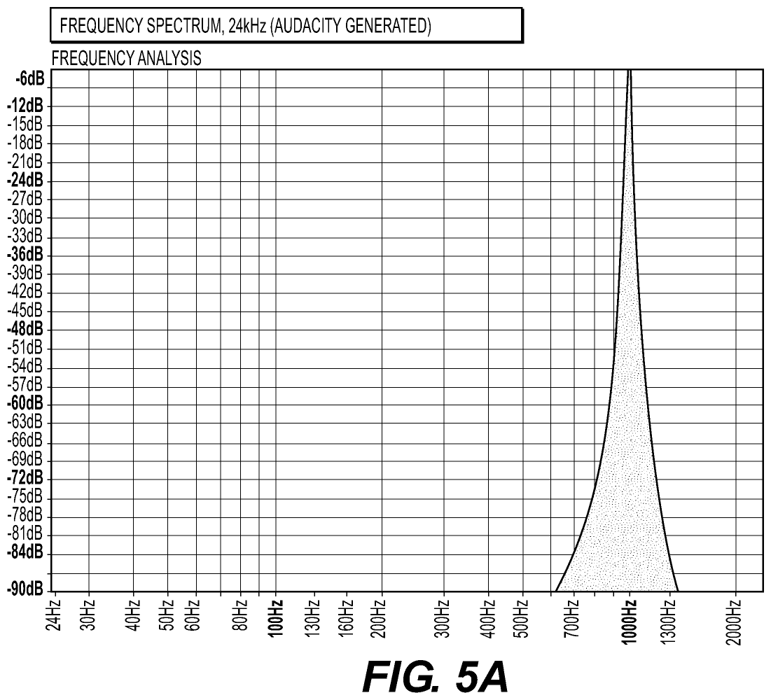

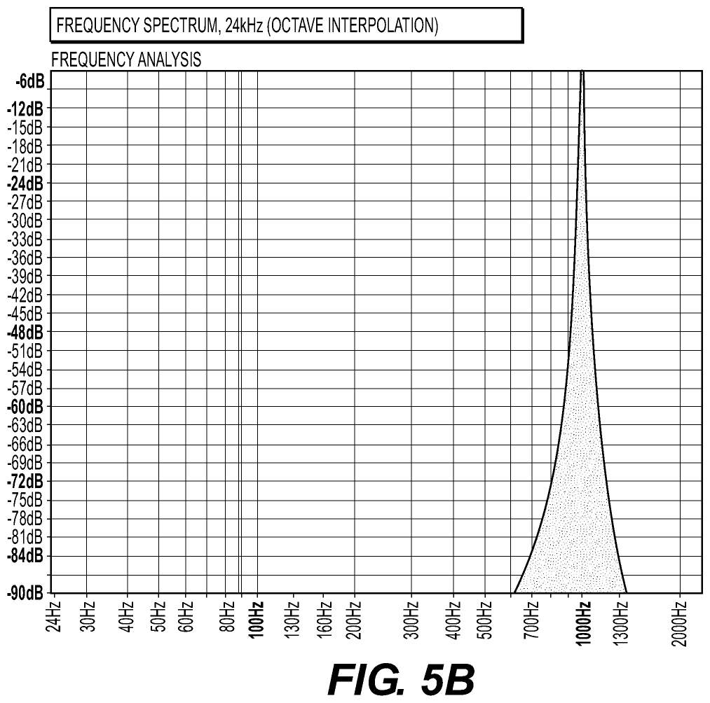

To illustrate how the interpolation can significantly recreate a signal that has been decimated, FIGS. 4A-7C show comparisons of simulated single and multi-frequency generated and interpolated signals. Specifically, FIG. 4A shows a sample signal or waveform with a single frequency and amplitude and FIG. 4B shows a single frequency generated 12 kHz sample signal of a waveform having only a single frequency and amplitude, a single frequency generated 24 kHz sample signal, and a single frequency interpolated 24 kHz sample signal. A 12 kHz .wav file (the single frequency generated 12 kHz sample signal) was created using signal processing software (e.g., Audacity). Similarly, a 24 kHz .wav file was created using Audacity (single tone of 1 kHz at 24 k samples/s). The 12 k .wav file was interpolated using a numerical computation program (e.g., Octave) to the single frequency interpolated 24 kHz sample signal. The single frequency interpolated 24 kHz sample signal was compared to the generated 24 kHz sample signal using Audacity. As shown, the single frequency interpolated 24 kHz sample signal matches the single frequency generated 24 kHz sample signal. FIGS. 5A and 5B show a comparison of the frequency spectrum of the single frequency generated 24 kHz sample signal (FIG. 5A) to the single frequency interpolated 24 kHz sample signal (FIG. 5B)(interpolated from the single frequency generated 12 kHz sample signal).

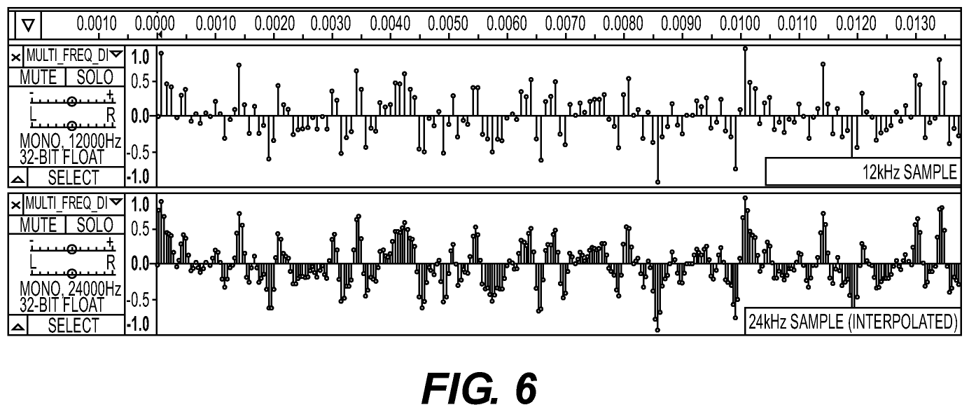

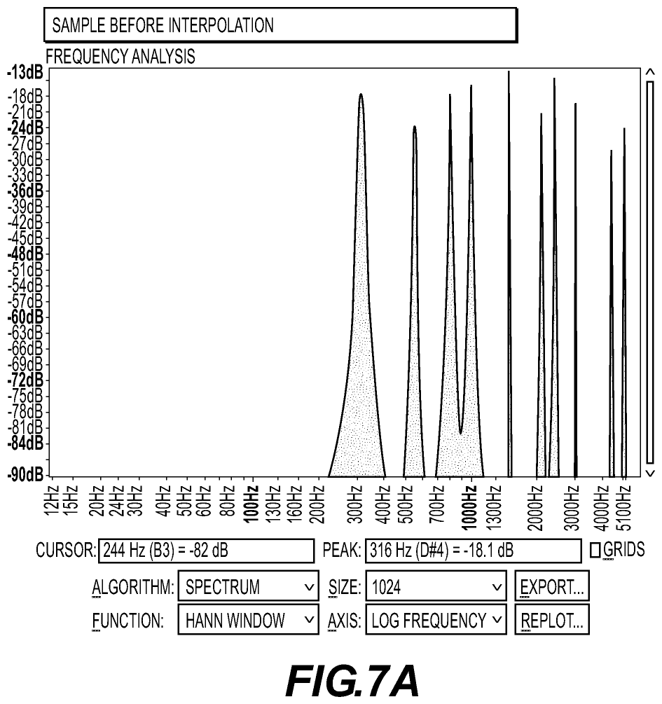

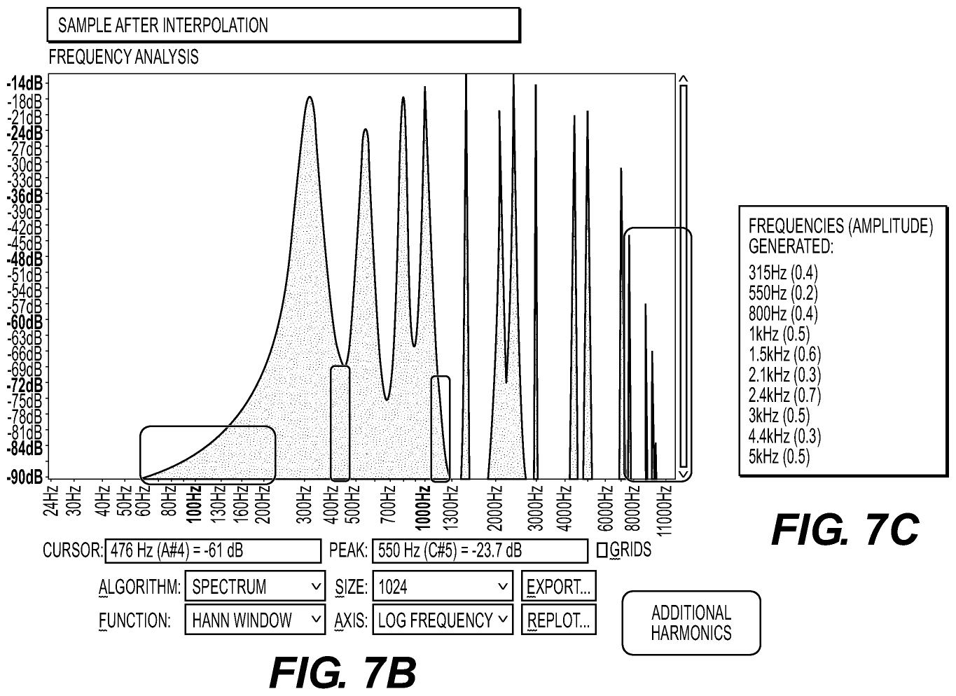

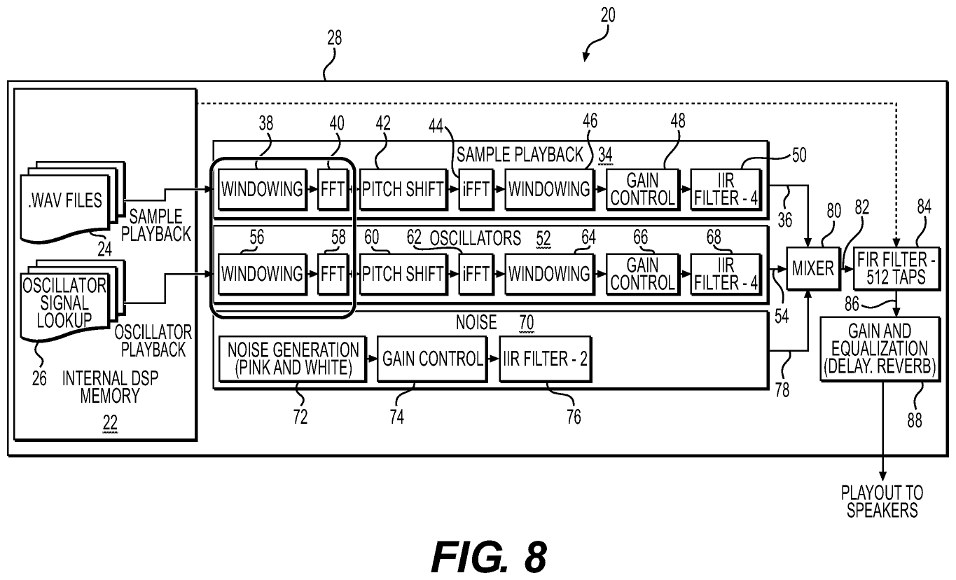

FIG. 6 shows a multi-frequency generated 12 kHz sample signal of a waveform having multiple frequencies and varying amplitudes and a multi-frequency interpolated 24 kHz sample signal. A 12 kHz .wav file (the multi-frequency generated 12 kHz sample signal) was created using Audacity (10 frequencies with varying amplitudes at 12 k samples/s). The 12 k .wav file was interpolated using Octave to a multi-frequency interpolated 24 kHz sample signal. The multi-frequency interpolated 24 kHz sample signal closely approximates the multi-frequency generated 24 kHz sample signal. While some minor losses were noted, such minor losses are not noticeable at target frequency ranges (315-5000 Hz). FIGS. 7A and 7B show a comparison of the frequency spectrum of the multi-frequency generated 12 kHz sample signal (FIG. 7A) to the multi-frequency interpolated 24 kHz sample signal (FIG. 7B) (interpolated from the multi-frequency generated 12 kHz sample signal). FIG. 7C shows the frequencies and amplitudes of the multi-frequency generated 12 kHz sample signal of FIG. 7A. As shown, interpolation of the multi-frequency signal generates additional harmonics (shown in the boxes)—these can be filtered out (e.g., with the FIR filter module).

So, referring back to FIG. 8, the block diagram of the audio processing system 20 of FIG. 1 is shown with particular modules or blocks highlighted that are eliminated in the at least one processing unit 128 of the audio processing system 120 disclosed herein. As discussed above, the windowing and FFT blocks or modules 38, 40, 56, 58 (highlighted in the box) are moved to the tuning tool 130 (blocks 192, 194, 196 of FIG. 2). Specifically, the functions of the first playback windowing module 38, the playback fast Fourier transform (FFT) module 40, the first oscillator windowing module 56, and the oscillator fast Fourier transform (FFT) module 58 will be processed by the tuning tool 130. The FFT output (i.e., output of the playback fast Fourier transform (FFT) module 40 and the oscillator fast Fourier transform (FFT) module 58) will be stored in the frequency domain (e.g., in the memory 122). Decimation by the tuning tool 130, processing at the second frequency (e.g., 12 kHz), and interpolation back to the first frequency (e.g., 24 kHz) helps provide a reduction in the amount of processing (i.e., reduced MIPS) and storage needed. It can reduce the MIPS requirement by approximately 13%. Such a reduction is possible because the sound and noise generation, mixing, and master gains are processed using smaller files (decimated to 12 kHz and in the frequency domain).

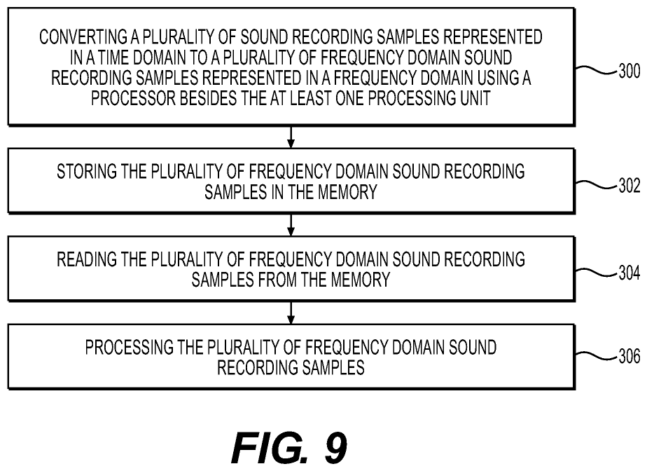

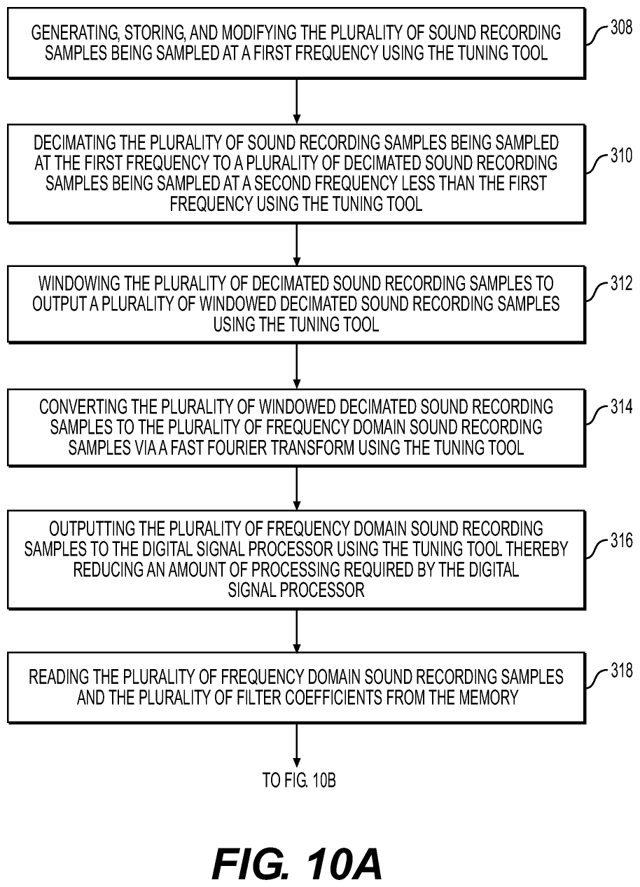

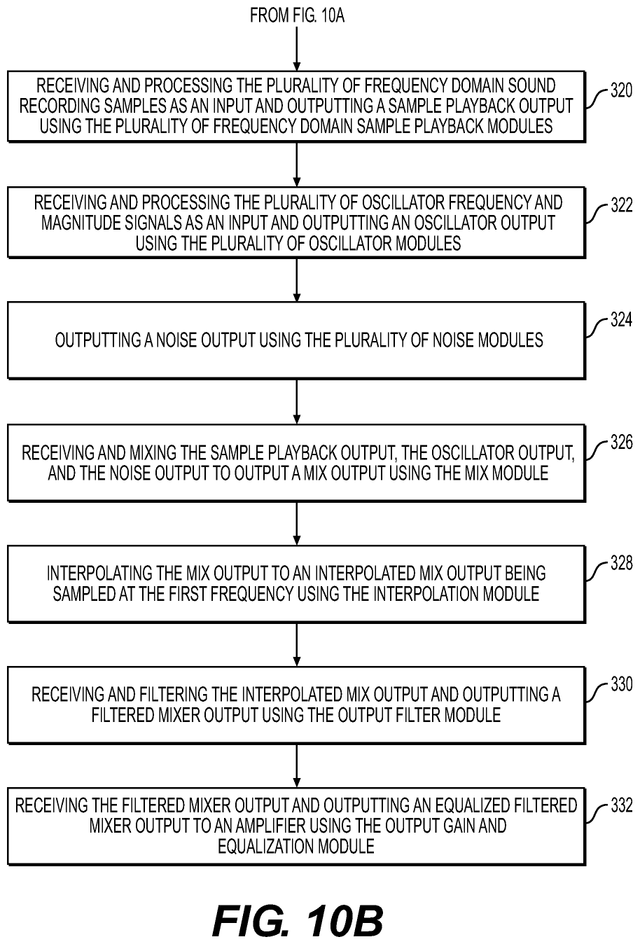

As best shown in FIGS. 9 and 10A-10B, a method of operating an audio processing system 120 including at least one processing unit 128 coupled to a memory 122 is also provided. Referring initially to FIG. 9, the method includes the step of 300 converting a plurality of sound recording samples represented in a time domain to a plurality of frequency domain sound recording samples 124 represented in a frequency domain using a processor besides the at least one processing unit 128. The method continues with the step of 302 storing the plurality of frequency domain sound recording samples 124 in the memory 122. The next step of the method is 304 reading the plurality of frequency domain sound recording samples 124 from the memory 122. The method also includes the step of 306 processing the plurality of frequency domain sound recording samples 124.

As discussed above, the at least one processing unit 128 includes the digital signal processor 128 and the system 120 further includes the tuning tool 130 configured to be selectively coupled to the digital signal processor 128. Thus, now referring to FIGS. 10A-10B, the method also includes the step of 308 generating, storing, and/or modifying the plurality of sound recording samples being sampled at a first frequency using the tuning tool 130. Next, 310 decimating the plurality of sound recording samples being sampled at the first frequency to a plurality of decimated sound recording samples being sampled at a second frequency less than the first frequency using the tuning tool 130. The method continues by 312 windowing the plurality of decimated sound recording samples to output a plurality of windowed decimated sound recording samples using the tuning tool 130. The next step of the method is 314 converting the plurality of windowed decimated sound recording samples to the plurality of frequency domain sound recording samples 124 via a fast Fourier transform using the tuning tool 130. The method proceeds by 316 outputting the plurality of frequency domain sound recording samples 124 to the digital signal processor 128 using the tuning tool 130 thereby reducing an amount of processing required by the digital signal processor 128.

Again, the memory 122 includes the plurality of frequency domain filter coefficients 132, the plurality of oscillator frequency and magnitude signals 126, and the single unity sine wave reference table 133. In addition, as discussed, the at least one processing unit 128 includes the plurality of frequency domain sample playback modules 134, a plurality of oscillator modules 152, the plurality of noise modules 170, the mix module 180, the interpolation module 183, the output filter module 184 (e.g., finite impulse response (FIR)), and the output gain and equalization module 188 (e.g., delay, reverb). So, the method includes the step of 318 reading the plurality of frequency domain sound recording samples 124 and the plurality of frequency domain filter coefficients 132 from the memory 122. The method continues with the step of 320 receiving and processing the plurality of frequency domain sound recording samples 124 as an input and outputting a sample playback output 136 using the plurality of frequency domain sample playback modules 134. Next, 322 receiving and processing the plurality of oscillator frequency and magnitude signals 126 as an input and outputting an oscillator output 154 using the plurality of oscillator modules 152. The method continues with the step of 324 outputting a noise output 178 using the plurality of noise modules 170. The next step of the method is 326 receiving and mixing the sample playback output 136, the oscillator output 154, and the noise output 178 to output a mix output 182 using the mix module 180. The method proceeds by 328 interpolating the mix output 182 to an interpolated mix output 185 being sampled at the first frequency using the interpolation module 183. The method continues with the step of 330 receiving and filtering the interpolated mix output 185 and outputting a filtered mixer output 186 using the output filter module 184. Then, the method also includes the step of 332 receiving the filtered mixer output 186 and outputting an equalized filtered mixer output 187 to an amplifier 189 using the output gain and equalization module 188 (e.g., delay, reverb).

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

What is claimed is:

1. An audio processing system comprising:
a memory storing a plurality of frequency domain sound recording samples represented and stored in a frequency domain and being previously converted from a plurality of sound recording samples represented in a time domain; and
at least one processing unit coupled to the memory and configured to:
read the plurality of frequency domain sound recording samples from the memory, and
process the plurality of frequency domain sound recording samples.

2. The audio processing system of claim 1, wherein the at least one processing unit includes a digital signal processor and the audio processing system further includes a tuning tool configured to be selectively coupled to the digital signal processor, the tuning tool configured to:
generate, store, and modify the plurality of sound recording samples being sampled at a first frequency; and
decimate the plurality of sound recording samples being sampled at the first frequency to a plurality of decimated sound recording samples being sampled at a second frequency less than the first frequency.

3. The audio processing system of claim 2, wherein the tuning tool is further configured to:
window the plurality of decimated sound recording samples to output a plurality of windowed decimated sound recording samples;
convert the plurality of windowed decimated sound recording samples to the plurality of frequency domain sound recording samples via a fast Fourier transform; and
output the plurality of frequency domain sound recording samples to the digital signal processor thereby reducing an amount of processing required by the digital signal processor.

4. The audio processing system of claim 2, wherein the memory also includes a plurality of frequency domain filter coefficients, a plurality of oscillator frequency and magnitude signals and a single unity sine wave reference table and the at least one processing unit is configured to read the plurality of frequency domain sound recording samples, plurality of oscillator frequency and magnitude signals, and the plurality of frequency domain filter coefficients from the memory; and the at least one processing unit includes:
a plurality of frequency domain sample playback modules configured to receive and process the plurality of frequency domain sound recording samples as an input and output a sample playback output;
a plurality of oscillator modules configured to receive and process the plurality of oscillator frequency and magnitude signals as an input and output an oscillator output;
a plurality of noise modules configured to output a noise output; and
a mix module configured to receive and mix the sample playback output, the oscillator output, and the noise output to output a mix output.

5. The audio processing system of claim 4, further including:
an interpolation module configured to interpolate the mix output to an interpolated mix output being sampled at the first frequency;
an output filter module configured to receive and filter the interpolated mix output and output a filtered mixer output; and
an output gain and equalization module configured to receive the filtered mixer output and output an equalized filtered mixer output to an amplifier.

6. The audio processing system of claim 5, wherein the output filter module comprises a finite impulse response filter.

7. The audio processing system of claim 4, wherein:
the plurality of frequency domain sample playback modules include a frequency domain playback pitch shift module, a frequency domain playback inverse fast Fourier transform module, a playback windowing module, a playback gain control module, and a playback filter module;
the plurality of oscillator modules include an oscillator generation and pitch shift module, an oscillator gain control module, and an oscillator filter module; and
the plurality of noise modules include a noise generator module, a noise gain control unit, and a noise filter module.

8. The audio processing system of claim 7, wherein:
the frequency domain playback pitch shift module, the frequency domain playback inverse fast Fourier transform module, the playback windowing module, the playback gain control module, and the playback filter module are successively connected to one another serially;
the oscillator generation and pitch shift module, the oscillator gain control module, and the oscillator filter module are successively connected to one another serially; and
the noise generator module, the noise gain control unit, and the noise filter module are successively connected to one another serially.

9. The audio processing system of claim 7, wherein the playback filter module comprises an infinite impulse response filter.

10. The audio processing system of claim 7, wherein the oscillator filter module comprises an infinite impulse response filter.

11. The audio processing system of claim 7, wherein the noise filter module comprises an infinite impulse response filter.

12. The audio processing system of claim 4, wherein the at least one processing unit is configured to:
read the plurality of oscillator frequency and magnitude signals and the single unity sine wave reference table from the memory; and
generate and output the oscillator output using the plurality of oscillator modules based on the plurality of oscillator frequency and magnitude signals and the single unity sine wave reference table.

13. A method of operating an audio processing system including at least one processing unit coupled to a memory, the method comprising the steps of:
converting a plurality of sound recording samples represented in a time domain to a plurality of frequency domain sound recording samples represented in a frequency domain using a processor besides the at least one processing unit;
storing the plurality of frequency domain sound recording samples in the memory;
reading the plurality of frequency domain sound recording samples from the memory; and
processing the plurality of frequency domain sound recording samples.

14. The method of claim 13, wherein the at least one processing unit includes a digital signal processor and the audio processing system further includes a tuning tool configured to be selectively coupled to the digital signal processor, the method further including the steps of:
storing the plurality of sound recording samples being sampled at a first frequency using the tuning tool; and
decimating the plurality of sound recording samples being sampled at the first frequency to a plurality of decimated sound recording samples being sampled at a second frequency less than the first frequency using the tuning tool.

15. The method of claim 14, further including the steps of:
windowing the plurality of decimated sound recording samples to output a plurality of windowed decimated sound recording samples using the tuning tool;
converting the plurality of windowed decimated sound recording samples to the plurality of frequency domain sound recording samples via a fast Fourier transform using the tuning tool; and
outputting the plurality of frequency domain sound recording samples to the digital signal processor using the tuning tool thereby reducing an amount of processing required by the digital signal processor.

16. The method of claim 15, wherein the memory also includes a plurality of frequency domain filter coefficients, a plurality of oscillator frequency and magnitude signals, a single unity sine wave reference table and the at least one processing unit includes a plurality of frequency domain sample playback modules, a plurality of oscillator modules, a plurality of noise modules, a mix module, an interpolation module, an output filter module, an output gain and equalization module, and the method includes the steps of:
reading the plurality of frequency domain sound recording samples and the plurality of frequency domain filter coefficients from the memory;
receiving and processing the plurality of frequency domain sound recording samples as an input and outputting a sample playback output using the plurality of frequency domain sample playback modules;
receiving and processing the plurality of oscillator frequency and magnitude signals as an input and outputting an oscillator output using the plurality of oscillator modules;
outputting a noise output using the plurality of noise modules;
receiving and mixing the sample playback output, the oscillator output, and the noise output to output a mix output using the mix module;
interpolating the mix output to an interpolated mix output being sampled at the first frequency using the interpolation module;
receiving and filtering the interpolated mix output and outputting a filtered mixer output using the output filter module; and
receiving the filtered mixer output and outputting an equalized filtered mixer output to an amplifier using the output gain and equalization module.

17. An audio processing system comprising:
a memory storing a plurality of oscillator frequency and magnitude signals and a single unity sine wave reference table; and
at least one processing unit coupled to the memory and including a plurality of oscillator modules and configured to:
read the plurality of oscillator frequency and magnitude signals and the single unity sine wave reference table from the memory, and
generate and output an oscillator output using the plurality of oscillator modules based on the plurality of oscillator frequency and magnitude signals and the single unity sine wave reference table.

18. The audio processing system of claim 17, wherein the memory stores a plurality of frequency domain sound recording samples represented and stored in a frequency domain and being previously converted from a plurality of sound recording samples represented in a time domain; the at least one processing unit is configured to:
read the plurality of frequency domain sound recording samples from the memory; and
process the plurality of frequency domain sound recording samples.

19. The audio processing system of claim 18, wherein the at least one processing unit includes a digital signal processor and the audio processing system further includes a tuning tool configured to be selectively coupled to the digital signal processor, the tuning tool configured to:
generate, store, and modify the plurality of sound recording samples being sampled at a first frequency; and
decimate the plurality of sound recording samples being sampled at the first frequency to a plurality of decimated sound recording samples being sampled at a second frequency less than the first frequency.

20. The audio processing system of claim 19, wherein the tuning tool is further configured to:
window the plurality of decimated sound recording samples to output a plurality of windowed decimated sound recording samples;
convert the plurality of windowed decimated sound recording samples to the plurality of frequency domain sound recording samples via a fast Fourier transform; and
output the plurality of frequency domain sound recording samples to the digital signal processor thereby reducing an amount of processing required by the digital signal processor.
